(19) United States
(12) Patent Application Publication
(10) Pub. No.: US 2020/0307098 A1
(43) Pub. Date: Oct. 1, 2020

(54) ENCODING IN THREE-DIMENSIONAL OBJECTS

(71) Applicant: HEWLETT-PACKARD DEVELOPMENT COMPANY, L.P., Spring, TX (US)

(72) Inventors: Juan Manuel Zamorano, Sant Cugat del Valles (ES); Mayid Shawi, Sant Cugat del Valles (ES); Vicente Granados, Sant Cugat del Valles (ES)

(21) Appl. No.: 16/605,605

(22) PCT Filed: Dec. 22, 2017
(86) PCT No.: PCT/US2017/068218

§ 371 Date: Oct. 16, 2019

(51) Int. Cl. B29C 64/386; H05K 1/16; H05K 3/12

(52) U.S. Cl. CPC B29C 64/386; H05K 1/162; B33Y 50/02; H05K 3/12; H05K 1/165

(57) ABSTRACT

Certain examples relate to encoding data into three-dimensional objects. In one case, a location of a set of terminals to be accessed on an outer surface of the object after fabrication is determined. A mapping between data to be encoded and an electrical property to be measured via a conductive coupling and an embedded electrical structure with the electrical property are determined. Control data is generated to instruct the fabrication of the object with the set of terminals and the embedded electrical structure.

### BACKGROUND

Additive manufacturing systems, including those commonly referred to as “3D printers”, provide a convenient way to produce three-dimensional objects. These systems may receive a definition of a three-dimensional object in the form of an object model. This object model is processed to instruct the system to produce the object using one or more material components. This may be performed on a layer-by-layer basis in a working area of the system. Some three dimensional printer systems operate by depositing a chemical binding agent onto a layer of a powder bed using print heads similar to those used for two dimensional printing. Other systems use the deposit of functional agents on a bed of build material, wherein the build material is selectively solidified under the influence of the functional agents, e.g. via the use of an energy source. Other techniques include selective laser sintering, where a laser is used to selectively solidify a powdered material such as nylon or a metallic powder, and fused deposition modelling, where a polymer or metallic wire may be melted and selectively deposited in layers.

### BRIEF DESCRIPTION OF THE DRAWINGS

FIG. 1 is a flow diagram showing a method of generating control data for a three-dimensional printer according to an example.

FIG. 2 is a schematic diagram showing a measurement performed on an object according to an example.

FIG. 3 is a flow diagram showing an example method of reading data from an object fabricated by a three-dimensional printing system.

FIG. 4 is a schematic cross section of a three-dimensional printing system according to an example.

FIG. 5 is a schematic diagram showing three example configurations for an embedded electrical structure.

FIG. 6 is a schematic diagram showing an example of a fabricated object.

FIG. 7 is a schematic diagram showing a non-transitory machine readable medium according to an example.

FIG. 8 is a schematic diagram showing measurement of a frequency response from an example object.

### DETAILED DESCRIPTION

Certain examples described herein relate to particular structures that are generated as part of a three-dimensional object during additive manufacturing. In one example, an electrical structure is embedded within a three-dimensional object. An electrical property of the structure may be measured after fabrication using, for example, conductive coupling. A measured value of the electrical property may then be used to determine data encoded within the object. The electrical structure may comprise a circuit with components such as resistors, inductors and capacitors.

In certain examples, an electrical structure may be fabricated within a three-dimensional object to act as an identifier, wherein a measured value from terminals on the outside of the object is used to determine an identifier value for the object. In this manner, objects may be traced and tracked. Uses include identification of parts, traceability including obsolescence control, part authentication and part or batch numbering.

Methods described herein may be applied to different additive manufacturing techniques where a conductivity of a build material may be controlled. For example, chemical agents, referred to as “functional agents”, may be selectively deposited onto a layer of build material. These functional agents may control a conductivity of the build material, e.g. by modifying chemical properties of the build material. In one case, the functional agent may comprise a dopant to modify the electrical properties of the build material, Alternatively, the three-dimensional printing system may be able to deposit both conductive and insulating materials (e.g. metallic and polymer build materials) to construct the electrical structure.

By generating embedded electrical structures, data may be physically encoded into an object as part of the manufacturing process. This may be contrasted with comparative systems, wherein electronic devices are inserted into, or applied onto, fabricated objects. By fabricating the electrical structure with the object, certain examples described herein may be more robust and secure, e.g. harder to manipulate.

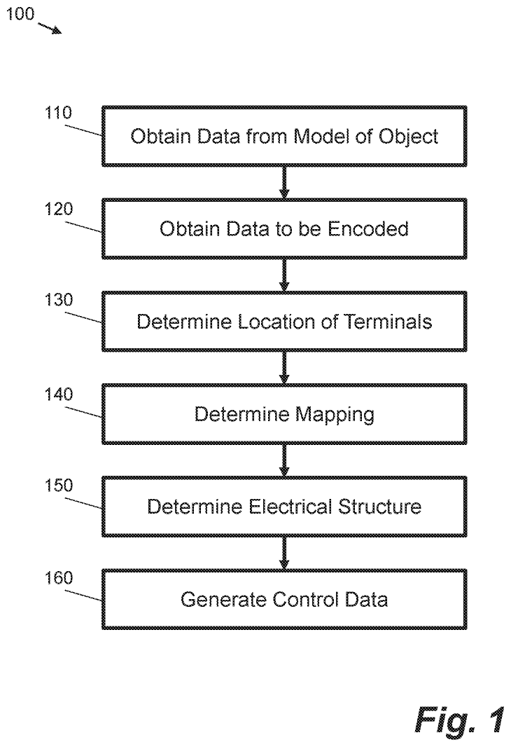

FIG. 1 shows an example method 100 of generating control data for use in fabricating an object. The method may be applied by a data processing apparatus that is communicatively coupled to a three-dimensional printing system. The three-dimensional printing system uses the control data to fabricate a three-dimensional object.

At block 110, data derived from a model of a three-dimensional object is obtained. The three-dimensional object is an object to be fabricated by the three-dimensional printing system. The model may comprise a Computer-Aided Design (CAD) model where a shape of the object is defined in a three-dimensional space. For example, the model may define the object as a series of geometric shapes having particular co-ordinates in three dimensions. Alternatively, the model may comprise a rasterized representation, wherein the three-dimensional object is defined based on a series of voxel values within the three-dimensional space, wherein a voxel represents a unit volume of the space. In yet another case, the model may define an object as a series of surfaces within the three dimensional space, each surface having an area and a normal vector. Other models and representations are also possible. The data derived from the model may comprise model data, e.g. voxel or vector shape definitions, data generated following processing of the model data (e.g. a three-dimensional shape in vector form may be converted to a rasterized voxel representation) and/or data representative of preprocessed model data. In any case, the data obtained at block 110 is useable to instruct the fabrication of the three-dimensional object on the three-dimensional printing system. The data may be obtained as part of print job information that is sent to the data processing apparatus. In certain cases, the data processing apparatus may form part of the three-dimensional printing system.

At block 120, data to be encoded into the object is obtained. This data may comprise an n-bit integer or floating point number. The data may alternatively comprise a set of alphanumeric characters. The data may be mapped to a particular bit pattern. The data may comprise an index for a structured data store, such that information associated with the object may be retrieved given the data. For example, the data may comprise an integer primary key value that is associated with a row of data in a relational database. The data may be defined as part of print job information that is received by the data processing apparatus. Alternatively, the print job information may indicate that an identifier is to be added to the object, and the data processing apparatus may generate the data, e.g. based on a predefined range of values or function. In one case, the data processing apparatus may select a value from a range of values (e.g. 2ⁿ values for an n-bit integer). The data processing apparatus may apply a constraint that the data is to be unique for each object, in which case a list of previously-assigned values may be stored and used to select new values that are not part of this list. In one case, the data processing apparatus may use a hashing or other cryptographic function to generate the data.

At block 130, a location of a set of terminals is determined. This determination may be made with respect to the three-dimensional model, e.g. placement is determined in relation to the shape and surfaces of the object as defined in the model. The set of terminals may comprise a set of conductive areas on an outer surface of the object that is accessible following fabrication. The set of terminals may be on a common surface of the object or on different surfaces of the object. Each terminal may be defined based on a predefined shape, e.g. a square or rectangular area or volume that is located on or within a boundary of the object. Each terminal may have a predefined absolute or relative size, The set of terminals may comprise two or more terminals. One terminal may comprise a positive terminal and one terminal may comprise a negative terminal. The set of terminals indicate where an embedded electrical structure comes to an end and provide a point of connection to external circuitry, i.e. via conductive coupling.

In certain cases, three-dimensional objects may undergo post-processing such as bead-blasting to remove one or more layers of material on the surface on the object or to smooth an outer appearance of the object. In these cases, the set of terminals may be located below an initial outer surface or layer of the object such that they are accessible following post processing.

At block 140, a mapping between the data to be encoded and an electrical property is determined. The electrical property is a property to be measured via a conductive coupling to the set of terminals. The mapping may be based on a predefined function. For example, in a simple case, the electrical property may be resistance and an integer value of the data to be encoded may be mapped to a resistance value. If the data is a 4-bit integer representing 16 possible values, and the resistance is defined to be within a range of 600 ohms to 2.2 kilohms, then each value may be mapped to the midpoint of a 100 ohm set of resistance values within this range (e.g. 650, 750, 2150). For more complex cases, the mapping may comprise linear and/or non-linear mapping functions, e.g. a logarithmic mapping may be used to take advantage of a large range of resistor values to encode larger ranges of data values. In one case, the electrical property may comprise a multi-dimensional property, e.g. measured values for two or more of resistance, capacitance and inductance. In certain scenarios, frequency response may be measured.

At block 150, following the determination of a desired value for the electrical property, an embedded electrical structure having the electrical property is determined. This may comprise selecting an electrical structure for embedding from a library of predefined electrical structures. In one case, the desired value of the electrical property may be used to select the electrical structure from the library, e.g. the library of predefined electrical structures may be indexed by electrical property value. In another case, the electrical property value may be used to instantiate a particular instance of an electrical structure selected from the library of predefined electrical structures, e.g. to finalize sub-elements of the selected electrical structure. The library of predefined electrical structures may be maintained by the data processing apparatus or any other application responsible for embedding electrical structures (and/or conductive traces and terminals) in a printed part.

Block 150 may alternatively, or also, comprise determining a configuration of one or more electrical structures that form an electrical circuit between a positive and negative terminal in the set of terminals. The embedded electrical structure is determined so as to be conductively coupled to the set of terminals. For example, the embedded electrical structure may comprise a resistor configuration having a resistance value as computed in block 140, where the resistor is conductively coupled by a series of traces to the set of terminals from block 130. The electrical structure is “embedded” as at least a portion of the structure is defined to reside within a volume of the object to be fabricated, e.g. as defined by the data obtained at block 110. In certain cases, the electrical structure may not be visible from outside of the object, e.g. may be located completely within an outer surface of the object with the terminals being visible; in other cases, the electrical structure may be partially embedded within an outer surface of the object. Both the electrical structure and the set of terminals may be defined by modifying data derived from the model of the three-dimensional object, e.g. by modifying material definition data for voxels that are to form part of these structures and/or by adding further vector objects to a model definition.

At block 160, control data is generated to instruct the fabrication of the object with the set of terminals and the embedded electrical structure. For example, this may comprise generating control data for the deposit of build material and/or functional agents that is sent to the three-dimensional printing system from the data processing apparatus. The control data may be generated in the form of z-slices that specify material properties for a plurality of voxels. Alternatively, or additionally, the control data may comprise an updated model of the three-dimensional object, i.e. with the set of terminals and the embedded electrical structure present in the model. Certain three-dimensional printing systems may be adapted to generate an object based on the updated model. The updated model may comprise an updated version of a model obtained in block 110. In certain cases, the control data includes instructions to manufacture the desired part in three-dimensions, together with the internal electrical structures, traces and terminals.

The method 100 allows data to be encoded within a three-dimensional object using the same process as is used to fabricate the three-dimensional object, e.g. via the synthesis of embedded conductive structures. Block 150 or block 160 may comprise defining a conductivity of portions of an internal volume of the object, e.g. by setting material properties for voxels in a digital model that are then converted into control instructions for the fabrication of solid portions from layers of build material. Conductivity may be controlled in certain examples through selective deposit of a functional agent. For example, the functional agent may be a conductive dopant that is applied to portions of build material in correspondence with the determined embedded electrical structure. The data to be encoded may comprise serial numbers, lot information and other identifying data associated with parts printed by the three-dimensional printing system.

In certain cases, internal electrical structures may be allocated to an object in a dynamic manner, e.g. each time an object is sent to be printed a different electrical structure may be generated. For example, a configuration of the embedded electrical structure may be randomly generated, This may be achieved by randomly sampling parameters for the electrical structure from a distribution of parameters. There may be multiple configurations of electrical structures that provide a given electrical property and one configuration may be selected from the set of possible configurations each time an object is printed. For example, a resistance of a resistor may be set based on parameters for volume, length and/or shape, wherein different configurations of volume, length and/or shape may result in a given value of resistance. By allocating internal electrical structures in a dynamic manner, including random allocation, it may be made more difficult to maliciously manipulate the internal electrical structures of the object, For example, the electrical structure may be in a different position for each object.

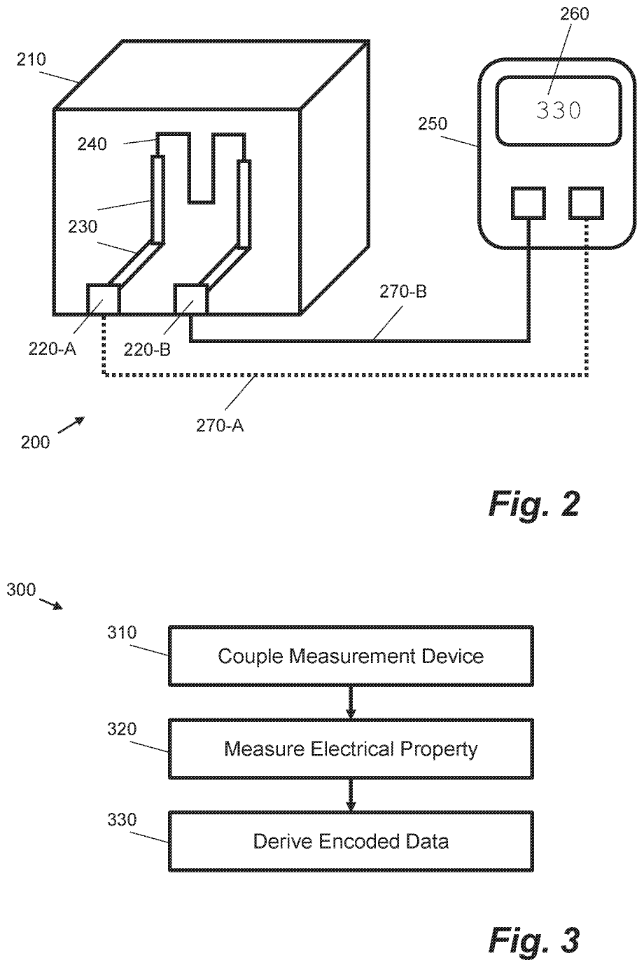

FIG. 2 shows a simple example 200 of a three-dimensional object 210 that may be fabricated according to the method of FIG. 1. In this example the object 210 is a cube, however the object may be fabricated to have any possible shape. The object in FIG. 2 has two terminals 220 that are conductively coupled to an embedded electrical structure comprising conductive traces 230 and resistive path 240. In this example, the conductive traces 230 and the resistive path 240 have a defined resistance value. The resistance value may be set via block 140 of FIG. 1. In FIG. 2, a desired resistance value sets the spatial configuration and/or conductivity of the resistive path 240. The conductive traces 230 couple a positive terminal 220-A and a negative terminal 220-B to the resistive path 240. The terminals 220 are located on a front surface of the object 210. The terminals 220 comprise special conductive areas that are accessible from a surface of the object 210. As described elsewhere, the terminals 220 may be used for active sensing as well as for passive sensing, e.g. measurement of a frequency response.

FIG. 2 also shows a measuring device 250 that may be used to measure the electrical property of the embedded electrical structure. In FIG. 2 the measuring device 250 comprises a multimeter with a display 260 that shows a measured value of the electrical property. In other examples, the measuring device 250 may be communicatively coupled to a computing device, e.g. via a connection such as a Universal Serial Bus connection, such that the measured value is accessible to the computing device. The computing device may be the aforementioned data process apparatus or comprise part of the three-dimensional printing system. In FIG. 2, a set of terminals of the measuring device 250 are conductively coupled to the terminals 220 accessible in the surface of the object 210 via connectors 270. The measured value in the example of FIG. 2 is “330”, which may relate to a resistance value of 330 ohms. This value may represent the encoded data directly (e.g. the object may have an identifier value of 330) or may be mapped to data associated with the object (e.g. may be used as input to a look-up table to retrieve another data value).

FIG. 3 shows a method 300 of reading data from an object fabricated by a three-dimensional printing system. The method 300 may be applied to a scenario such as that shown in FIG. 2. At block 310, a measurement device is conductively coupled to a set of terminals accessible on a surface of the object. For example, in FIG. 2, the first and second terminals 220-A, 220-B of the object are respectively coupled via connections 270-A, 270-B to terminals of the measurement device. It should be noted that the terminals may not comprise a planar area such as shown in FIG. 2; instead they may form part of a plug or other mechanical coupling with conductive contacts.

At block 320, an electrical property of an embedded electrical structure within the fabricated object is measured with the measurement device. In FIG. 2, the embedded electrical structure comprises conductive traces 230 and resistive path 240; in other examples, the electrical structure may comprise multiple electrical components, such as resistors, capacitors and inductors that are configured within a volume of the object. If multiple electrical components are provided they may be connected in series and/or parallel by sets of conductive traces. An electrical property to be measured may be influenced by each component. The contribution of each component to the electrical property may be configured by selecting a particular shape, e.g. within three-dimensional space. A given shape may have parameters of length, width and volume, amongst others. The embedded electrical structure is generated by the three-dimensional printing system during fabrication.

At block 330, data encoded within the fabricated object is derived from the measured electrical property. As mentioned above, this may be a direct derivation, e.g. the data may comprise the value of the measured property, or data may be derived through a look-up operation that uses the value of the measured property. In certain cases, an object may be identified by measuring a frequency response from the set of terminals.

In certain cases, a calibration element may also be embedded within the object along with the embedded electrical structure. The calibration element may also be generated by the three-dimensional printing system during fabrication, e.g. in a similar manner to the embedded electrical structure. The calibration element may be connected to one or more of the terminals located upon the object, or may be connected to additional terminals, e.g. additional terminals placed during block 130 of FIG. 1. The calibration element may be used to calibrate a measurement of the electrical property. In this case, method 300 may comprise measuring an electrical property of the calibration element, retrieving a predefined value for the electrical property of the calibration element, and calibrating the measurement of the electrical property of the embedded electrical structure based on a comparison between the measured value and the predefined value of the electrical property of the calibration element. For example, if the calibration element is a resistor of 10 ohms, and a measured value of the resistor is found to be 11 ohms, then a measured value of the electrical property of the embedded electrical structure may be multiplied by 10/11. In other examples, the calibration element may be one or more of a resistor, capacitor and inductor with predefined resistance, capacitance and inductance values. In this manner, a calibration element may help reduce an impact of temperature or other environmental factors on the measurement of the electrical property of the embedded electrical structure.

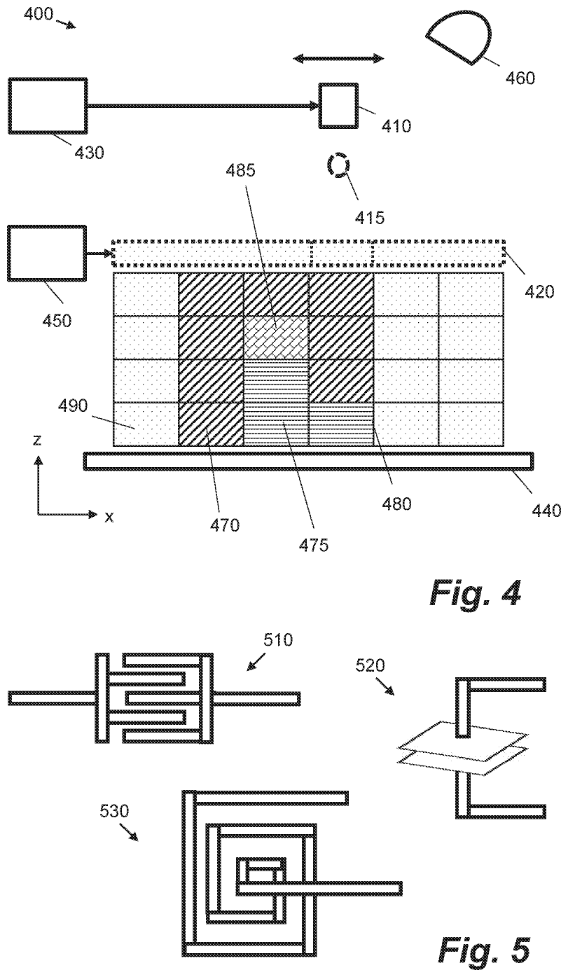

FIG. 4 shows an example of components of a three-dimensional printing system 400 that may be used to generate the objects discussed herein. It should be noted that FIG. 4 is a schematic diagram, and as such certain components may not be shown for clarity. Furthermore, the three-dimensional printing system 400 is described to better explain certain examples and may vary in configuration and technology for particular implementations.

In FIG. 4, an object to be fabricated is constructed from a number of layers of build material. Each layer of build material may have a thickness in the z-axis. In one case, this thickness may be between 70-120 microns, although in other examples thicker or thinner layers may be formed. The build material may comprise a powder or fibre-based build material. The three-dimensional printing system 400 is arranged to solidify portions of build material in each successive layer in accordance with the selective deposit of a functional agent.

The three-dimensional printing system 400 comprises a print head 410. The print head 410 is arranged to selectively deposit a functional agent 415 upon a bed of build material 420. The print head 410 may be moveable relative to the bed of build material 420. In one case, the print head 410 may be located in a moveable carriage located above the bed of build material 420. The print head may move in one or two directions over the bed of build material 420. In another case, the bed of build material 420 may be moveable underneath a static print head. Various combinations of approaches are possible.

In use, “selectively deposit” may refer to the controlled deposit of drops of functional agent on addressable areas of the bed of build material 420. For example, the three-dimensional printing system 400 may control relative movement between the print head 410 and an upper surface of the bed of build material 420, such that one or more drops of functional agent may be deposited in one of N*M areas of the upper surface, where N is an x-axis (print) resolution and M is a y-axis (print) resolution. An example drop size is 9 picolitres, although larger or smaller drop sizes are possible depending on the print head configuration. This may be a similar process to printing ink on a print medium such as paper. The functional agent may comprise a liquid that is ejected by an ejection mechanism of the print head 410. For example, the print head 410 may comprise a plurality of nozzles that may be independently controlled to eject the functional agent. The ejection mechanism may be based on piezo-electric or thermal elements. The three-dimensional printing system 400 may have a resolution similar to that of a two-dimensional printing system, e.g. 600 or 1200 dots per square inch (DPI).

In one case, the functional agent may comprise an energy-absorbing fusing agent. In this case, the fusing agent is selectively applied to a layer in areas where particles of the build material are generally to fuse together. Energy may then be applied, such as using an infrared lamp, to fuse areas of a layer based on the deposit of fusing agent. A detailing agent may also be applied to control thermal aspects of a layer of build material, e.g. to provide cooling of portions of the layer. The general process of applying a functional agent and solidifying according to an object model may then be repeated for further layers until the object is fabricated.

In FIG. 4, the print head 410 is controlled by a print controller 430. The print controller 430 may obtain or receive the control data generated by the method of FIG. 1 and use this data to instruct the deposit of one or more functional agents. The print controller 430 may comprise a processor and memory, wherein the processor is configured to execute instructions retrieved from the memory to fabricate a three-dimensional object according to data derived from an object model.

In one example, there may be multiple functional agents. Different print heads may be provided to deposit drops of different functional agents. Each functional agent may be configured to modify a property of a portion of build material. These agents may also be referred to as transformative agents. The property may comprise a color property and/or a material property of the build material. In one case, a functional agent may comprise a dopant to affect a conductivity of a portion of build material. In this case, conductive traces and terminals may be highly doped with conductive agents to reduce and/or minimize resistance. Other components such as resistors may receive a lower quantity of a conductive agent to control a conductivity of the component, wherein the combination of resistor shape and conductivity determine a resistance. Both the shape and the conductivity may be determined at block 150 in FIG. 1. Portions of build material outside of the designated electrical structure and set of terminals may not receive any dopant such that they act as an electrical insulator. The conductive dopant may in certain cases be based on one or more of carbon, carbon black, carbon fibre or graphene.

Returning to FIG. 4, an example cross section of an object is also shown. The object is formed within layers of build material that are deposited on a platen 440. The platen 440 may form part of the three-dimensional printing system 400. Also shown is a build material supply system 450 that is configured to successively form layers of build material over the platen 440. At startup, there may be no layers of build material upon the platen 440, as such build material supply system 450 may deposit a layer 420 upon the upper surface of the platen 4400. Subsequent layers may then be deposited on top of previous layers. Although not shown in FIG. 4, in certain examples one or more layers of build material may be deposited before fabrication begins, e.g. to form an initial bed of build material to build upon. The platen 440 may move relative to the build material supply system 450 during fabrication, e.g. the platen may move downwards in the z-direction. In certain examples, the platen 440 may form part of a build unit that is removable from the three-dimensional printing system 400, e.g. to allow extraction of fabricated objects. One three-dimensional printing system 400 may have multiple replaceable build units. In other examples, the platen 440 may form an integral part of the three-dimensional printing system 400.

The three-dimensional printing system 400 of FIG. 4 also comprises an energy source 460 to apply energy to an upper layer of build material. The energy source may comprise an infra-red lamp to apply energy substantially uniformly to the upper layer of build material. In this example, use of a fusing agent and/or a detailing agent may control a thermal profile of each layer under the influence of the energy source 460, such that the build material solidifies, e.g. fuses, according to control data obtained by the print controller 430. In the schematic example of FIG. 4, four solidified layers in the z-direction are shown, wherein each layer has six addressable portions in an x-direction. The object shown in FIG. 4 has portions of build material with different material properties. Portions 470, shown with a diagonal hatched line, comprise solidified portion of build material that act as an insulator, e.g. which did not receive deposits of a conductive dopant. Portions 475, shown with a horizontal hatched line, comprise solidified portions of build material that are conductive. For example, these portions may receive quantities of a fusing agent and/or a conductive dopant during fabrication. These portions may be similar to conductive traces 230 as shown in FIG. 2. A surface of portions 475 that is accessible on a face of the object forms a portion of a terminal 480, such as terminals 220 in FIG. 2. Portion 485, shown with diagonal hatched lines in two directions, comprises a solidified portion with a controlled level of conductivity, e.g. via a controlled level of a deposited conductive dopant. Portion 485 may form part of resistive path 240 as shown in FIG. 2. The portions 470, 475 and 485 are surrounded by portions of unfused build material 490. Following fabrication, the unfused build material 490 may be removed to reveal the object.

The example shown in FIG. 4 shows how functional agents in a three-dimensional printing system 400 may be deposited on a bed of build material to change material properties in a permanent manner after a fusing process takes place. For example, a chemical dopant may change a conductivity of portions of build material following fusion of those portions. By selectively modifying the conductivity of portions of solidified build material that form part of a three-dimensional object, printed circuits may be embedded in printed three-dimensional parts.

It should be noted that although the three-dimensional printing system 400 of FIG. 4 shows a specific three-dimensional printing technology as an example, other forms of three-dimensional manufacturing processes may be used in other examples. For example, a fused deposition modelling system may deposit different materials with different properties to construct the embedded electrical structure.

FIG. 5 shows three examples of different electrical structures that may form part of an embedded electrical structure. It should be noted that the examples shown in FIG. 5 may be combined to generate more complex electrical circuits. Many different implementations of electrical structures are possible in practice.

A first example provides a capacitive structure 510 via a set of interlocking conductive traces that are separated by a small insulating gap, the insulating gap being provided by portions of solidified build material. For example, in one case the build material may comprise a polymer powder, such as a polyimide, that acts as an electrical insulator following fusion. However, a functional agent may be conductive (e.g. comprise a conductive liquid or comprise conductive particles in a carrier liquid). In one case, the functional agent coats particles of build material yet still allows the polymer particles to fuse, e.g. following application of an energy source such as an infra-red lamp. The conductive traces in the capacitive structure 510 may thus comprise solidified build material that have been treated with the functional agent. By varying the spatial configuration and number of the interlocking conductive traces, a capacitance of the structure may be varied.

A second example provides an alternative capacitive structure 520. This capacitive structure comprises two conductive plates that are separated by an insulating gap, e.g. of solidified, undoped build material. By configuring the size of the plates, e.g. within a plane of voxels in a digital model, a capacitance of the structure may be varied.

A third example provides an inductive structure via a set of nested conductive traces. In this case, an inductance may be varied by modifying the number and/or size of the nested coils.

In a similar manner, an electrical property of resistive components, such as resistive path 240 in FIG. 2, may be controlled by determining one or more of a length and a shape of a conductive path. Additionally, a conductivity of one or more portions of the path may also be controlled to set the resistance of the component. It is also possible to control multiple properties, e.g. the conductivity of portions of the structures shown in FIG. 5 may be controlled to set a resistance as well as a capacitance or inductance.

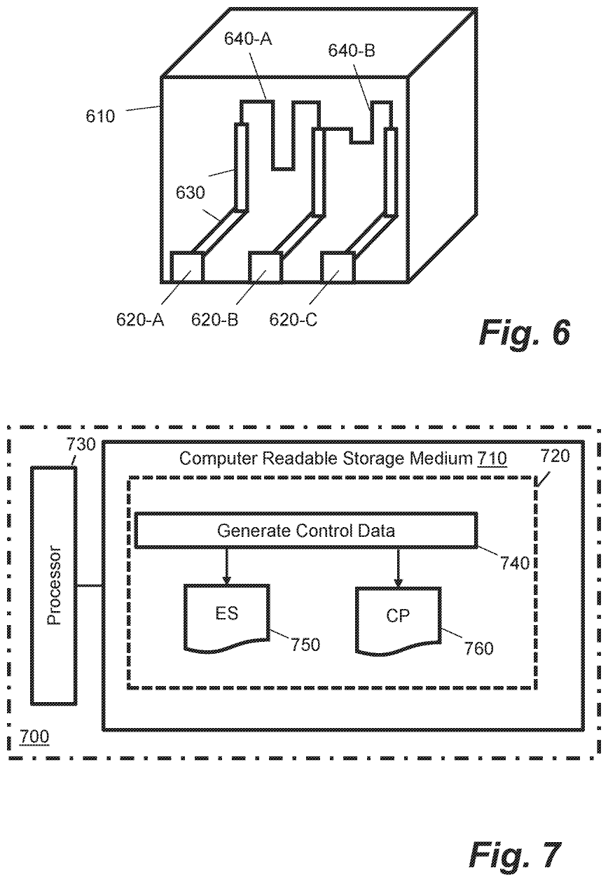

FIG. 6 shows an example object 610 where multiple terminals and embedded structures are provided. In this case there are three terminals: a first terminal 620-A, a second terminal 620-B and third terminal 620-C. A first resistive path 640-A with a first resistance is configured between the first and second terminals 620-A, B; a second resistive path 640-B with a second resistance is then configured between the second and third terminals 620-B, C. In this example, the first and second resistances differ, e.g. based on the different spatial configurations of the first and second resistive paths 640-A, B as shown in FIG. 6. In other examples, the first and second resistances may be equal. In this example, the first terminal 620-A may be used as a common measurement terminal. As such, a measurement may comprise conductively coupling a measurement device to the first and second terminals 620-A, B and measuring a first electrical property, In this example, the electrical property may comprise the first resistance. A measurement may then comprise conductively coupling the measurement device to the first and third terminals 620-A, C and measuring a second electrical property. The second electrical property in this case may comprise a sum of the first and second resistances. As such, a first value encoded within the fabricated object may be derived from the measured first electrical property and a second value encoded within the fabricated object may be derived from the measured second electrical property, Using multiple terminals and embedded structures may thus allow multiple values to be encoded into the object, e.g. both lot and part identifiers.

A general case of the example of FIG. 6 may be considered. If there are r different resistance values and m different components in series, then r^{m} different values may be encoded. By selecting r and m a given range of values may be encoded. For example, a range of 8-bit integers may use 4 resistance values that may be configured in paths of up to 4 components in series. In one case, different values may be encoded by only placing one set of two terminals, e.g. if the second terminal 620-B is not placed into the object definition then the example of FIG. 6 would encode a different value to that of FIG. 2. In one case, a given identifying value may be mapped to a frequency response that may be measured as the electrical property.

FIG. 7 shows a computer device 700 comprising a non-transitory computer-readable storage medium 710 storing instructions 720 which, when loaded into memory and executed by at least one processor 730, cause the processor to generate control data 740 for a three-dimensional printing system to fabricate a three-dimensional object. The computer-readable storage medium 710 may comprise any machine-readable storage media, e.g. such as a memory and/or a storage device. Machine-readable storage media can comprise any one of many physical media such as, for example, electronic, magnetic, optical, electromagnetic, or semiconductor media. More specific examples of suitable machine-readable media include, but are not limited to, a hard drive, a random access memory (RAM), a read-only memory (ROM), an erasable programmable read-only memory, or a portable disc. In one case, the processor 730 may be arranged to store instructions 720 in memory such as RAM to implement the complex event processing engine.

The instructions 720 are configured to cause the processor to, via instruction 740, generate control data that includes electrical structure instructions 750 and conductive pathway instructions 760. The electrical structure instructions 750 provide instructions for the three-dimensional printer to generate an electrical structure within an internal volume of the object to be produced. The conductive pathway instructions 760 provide instructions for the three-dimensional printer to generate a conductive pathway that includes the electrical structure and that enables an electrical property to be measured via conductive coupling, wherein the electrical property has a value that is mapped to data associated with the three-dimensional object. Hence, the computer readable storage medium 710 may comprise instructions 720 that enable a processor to perform a method similar to that described with reference to FIG. 1.

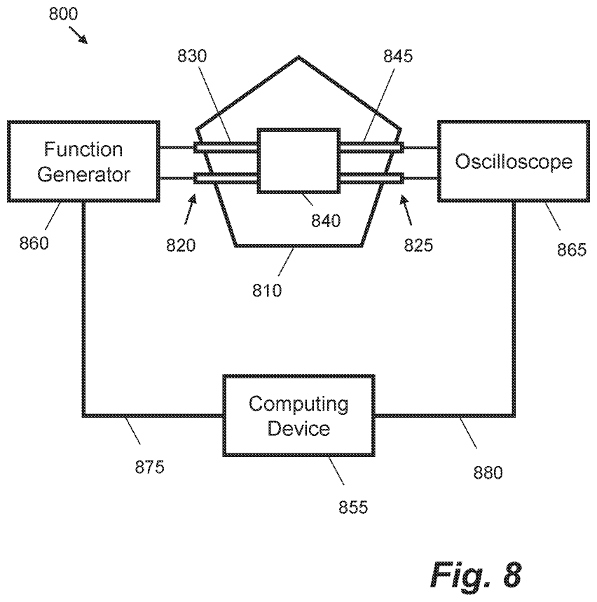

FIG. 8 shows an example of a three-dimensional object 810. Previous examples have comprised terminals that enable measurement of electrical properties of internal circuits. In certain examples, more complex electrical structures, e.g. comprising multiple resistors, capacitors and inductors, may be provided. In these examples, a limited number of external terminals may be provided to sense electrical properties of the structure. FIG. 8 shows one of these more complex examples.

FIG. 8 shows the three-dimensional object 810 having a set of input terminals 820 and a set of output terminals 825. The set of input terminals 820 are coupled to conductive traces 830. The conductive traces 830 are in turn coupled to an embedded electrical structure 840. The embedded electrical structure 840 is also coupled to the output terminals 825 via conductive traces 845.

In this example, the embedded electrical structure is configured to generate a particular frequency response. For example, an input waveform may be applied to the input terminals 820 and an output waveform may be measured from the output terminals 825. FIG. 8 shows a computing device 855 that is coupled to a function generator 860 and an oscilloscope 865. In other examples, each of the function generator 860 and the oscilloscope 865 may be coupled to separate computing devices, and/or incorporated into the computing device 855 or other devices. In this configuration, the function generator 860 may generate an electrical signal containing a specific set of frequencies and apply this signal to the input terminals 820. The embedded electrical structure 840 may act as an n-order filter that attenuates or otherwise modifies the input signal. An output electrical signal may then be measured from the output terminals 825 using the oscilloscope 865. The form of the output electrical signal may then be processed to decode data encoded with the object. For example, the embedded electrical structure 840 may implement a 5-order filter including a set of five poles and zeros at specific frequencies. These poles and zeroes may be determined by feeding electrical signals into the input terminals 820 and sensing a response on the output terminals 825.

With examples similar to that of FIG. 8, where a frequency response is measured, each object may generate a different response across a set of predefined frequencies. This response may encode data associated with the object, such as an identifier values. Multiple data values may be encoded within an object, wherein each value may be associated with a different frequency or frequency range. In this case, measurement may be made with one set of input terminals and one set of output terminals. Attenuation may be measured for each of a number of input frequencies. Data values such as identifiers may then be encoded on different attenuation values.

Certain examples have been described wherein passive electronic components may be embedded into a structure of a part printed by a three-dimensional printing system. In examples, components form part of an electrical structure that is printed within a desired internal volume of an object, wherein conductive traces and terminals are also fabricated as part of the object to allow measurement. In certain examples, an additive manufacturing device modifies conductive properties of one or more build materials to generate the electrical structure. In certain examples, an object definition that forms part of a print job may be modified to include instructions to generate the embedded electrical structure. Hence, a modified print job includes data for one or more objects with embedded data together with the appropriate conductive traces to read that data. The modified print job may then be sent to a three-dimensional printer to produce the one or more objects.

Certain examples described herein enable data to be encoded in a three-dimensional object in a flexible and configurable manner. For example, at print time, identifier values for parts may be dynamically set to implement serial numbers, lot numbers and/or batch numbers. By suitably selecting the design space of electrical structures, varying ranges of identifiers can be embedded. By generating the electrical structure in tandem with the object, issues with comparative solutions that physically insert circuits into fabricated parts may be avoided and the manufacturing process may be simplified. Also, by embedding electrical circuits into the structure of an object to be fabricated, hacking and manipulation of encoded data may be reduced or avoided. This means that embedded electrical structures form a more robust solution that is able to function throughout a life of a printed part.

Certain examples described herein may internally allocate electrical structures in a dynamic way, such that specific control data is generated for each part and such that different parts have different internal electrical structures. This may help against manipulation (so-called “hacking”) of parts. In these cases, two copies of an identical three-dimensional object may have different internal structures represented by differently allocated embedded electrical structures. In one case, even though internal structures may be dynamically allocated, a position of a set of terminals may stay constant (e.g. may be in the same place for a given object). In certain cases, a library of predefined electrical structures may be managed by a printing application in order to embed electrical structures with desired electrical properties in printed parts.

1. A method comprising:
obtaining data derived from a model of a three-dimensional object to be fabricated by a three-dimensional printing system;
obtaining data to be encoded into the object;
determining a location of a set of terminals to be accessed on an outer surface of the object after fabrication;
determining a mapping between the data to be encoded and an electrical property to be measured via a conductive coupling to the set of terminals;
determining an embedded electrical structure with the electrical property to be fabricated within the outer surface of the object, the embedded electrical structure being determined so as to be conductively coupled to the set of terminals; and
generating control data to instruct the fabrication of the object with the set of terminals and the embedded electrical structure.

2. The method of claim 1, wherein determining an embedded electrical structure comprises:
determining a level of a conductive dopant to use in portions of the object corresponding to the embedded electrical structure.

3. The method of claim 1, wherein determining an embedded electrical structure comprises:
determining a configuration of one or more structures from a set of capacitive structures, inductive structures and resistive structures for the embedded electrical structure.

4. The method of claim 3, wherein determining a configuration of one or more structures comprises:
randomly generating a configuration of the one or more structures such that the embedded electrical structure has the electrical property.

5. The method of claim 1, wherein determining an embedded electrical structure comprises:
determining a length of a conductive path between the set of terminals.

6. The method of claim 1, wherein determining an embedded electrical structure comprises:
determining a shape of a conductive path between the set of terminals.

7. The method of claim 1, comprising:
fabricating the object by:
forming layers of build material;
selectively applying functional agents to the layers of build material; and
selectively solidifying the layers of build material in accordance with the application of the functional agents,
wherein the functional agents are applied to generate conductive portions of the embedded electrical structure.

8. The method of claim 1, wherein determining a location of a set of terminals comprises:
locating the set of terminals below a layer of the object that is to be removed during post processing.

9. The method of claim 1, wherein determining a location of a set of terminals comprises:
identifying at least two areas on a surface of the object for placement of a predefined terminal design; and
wherein determining an embedded electrical structure comprises:
identifying a volume of the object in which to fabricate one or more structures defined in a library of electrical structures; and
determining a configuration of the one or more structures within the volume that has the electrical property.

10. The method of claim 1, comprising:
determining a range of data values for identifying a set of objects;
defining a set of embedded electrical structure designs; and
defining a parametric model that maps the range of data values to the set of embedded electrical structure designs.

11. A method of reading data from an object fabricated by a three-dimensional printing system, comprising:
conductively coupling a measurement device to a set of terminals accessible on a surface of the fabricated object;
measuring, using the measurement device, an electrical property of an embedded electrical structure within the fabricated object, the embedded electrical structure being generated by the three-dimensional printing system during fabrication; and
deriving data encoded within the fabricated object from the measured electrical property,

12. The method of claim 11, wherein the object comprises three or more test terminals and the method comprises:
conductively coupling the measurement device to first and second terminals in the set of test terminals;
measuring, using the measurement device, a first electrical property;
conductively coupling the measurement device to first and third terminals in the set of test terminals;
measuring, using the measurement device, a second electrical property; and
deriving a first value encoded within the fabricated object from the measured first electrical property and deriving a second value encoded within the fabricated object from the measured second electrical property.

13. The method of claim 11, comprising:
measuring an electrical property of a calibration element embedded within the object, the calibration element being generated by the three-dimensional printing system during fabrication;
retrieving a predefined value for the electrical property of the calibration element;
calibrating the measurement of the electrical property of the embedded electrical structure based on a comparison between the measured value and the predefined value of the electrical property of the calibration element.

14. The method of claim 11, wherein deriving data encoded within the fabricated object comprises:
using a measured frequency response to identify the object.

15. A non-transitory machine readable medium comprising instructions which, when loaded into memory and executed by at least one processor, cause the processor to:
generate control data for a three-dimensional printing system to fabricate a three-dimensional object, wherein the control data includes:
instructions for the three-dimensional printer to generate an electrical structure within an internal volume of the object, and
instructions for the three-dimensional printer to generate a conductive pathway that includes the electrical structure and that enables an electrical property to be measured via conductive coupling,
wherein the electrical property has a value that is mapped to data associated with the three-dimensional object.
